(19) United States
(12) Patent Application Publication
(10) Pub. No.: US 2024/0145283 A1
(43) Pub. Date: May 2, 2024

(54) Gas Supply System

(71) Applicant: Daifuku Co., Ltd., Osaka-shi (JP)

(72) Inventor: Tadashi Nishikawa, Hinocho (JP)

(21) Appl. No.: 18/385,715

(22) Filed: Oct. 31, 2023

(30) Foreign Application Priority Data
Nov. 1, 2022 (JP) 2022-175653

(51) Int. Cl. H01L 21/673; B65G 17/12; H01L 21/677

(52) U.S. Cl. CPC H01L 21/67389; B65G 17/12; H01L 21/67724; H01L 21/6773; H01L 21/67733

(57) ABSTRACT

A gas supply system includes a gas supply vehicle configured to supply an inactive gas to a transport vehicle. The transport vehicle includes a supply receiving section configured to receive the inactive gas supplied from the gas supply vehicle; and a first supply device configured to supply, to a container, the inactive gas supplied to the supply receiving section. The gas supply vehicle is further configured to travel along a travel path, and the gas supply vehicle includes a holding section configured to detachably hold a gas tank filled with the inactive gas; a supply section configured to be connected to and disconnected from the supply receiving section; and a second supply device configured to supply the inactive gas from the gas tank held by the holding section to the supply section.

### CROSS-REFERENCE TO RELATED APPLICATION

This application claims priority to Japanese Patent Application No. 2022-175653 filed Nov. 1, 2022, the disclosure of which is hereby incorporated by reference in its entirety.

### BACKGROUND OF THE INVENTION

### 1. Field of the Invention

The present invention relates to a gas supply system for supplying an inactive gas into a container, the gas supply system including a transport vehicle configured to travel along a predetermined travel path to transport the container.

### 2. Description of Related Art

For example, semiconductor wafers and glass substrates are transported by transport vehicles while being housed in specialized containers in a semiconductor manufacturing plant and the like. In the containers, an inactive gas is injected as a purge gas in order to, for example, suppress oxidation of semiconductor wafers and the like, or prevent dust from adhering to semiconductor wafers and the like. Such a technique is disclosed in JP 2016-021429A (Patent Document 1), for example.

In this type of field, a purge stocker that stores containers, and supplies an inactive gas to the stored containers is often used, as also disclosed in Patent Document 1. However, in order to supply the inactive gas into a container, the transport vehicle needs to transport the target container to the purge stocker. Furthermore, the inactive gas can only be supplied while the container is stored in the purge stocker.

### SUMMARY OF THE INVENTION

In view of the foregoing circumstances, it is desirable to realize a gas supply system that can supply an inactive gas to a container that is being transported by a transport vehicle.

A technique for solving the above-described problem is as follows.

A gas supply system configured to supply an inactive gas into a container, the gas supply system including:
a transport vehicle configured to travel along a predetermined travel path and transport the container; and
a gas supply vehicle configured to supply the inactive gas to the transport vehicle,
wherein the transport vehicle includes:
   a supply receiving section configured to receive the inactive gas supplied from the gas supply vehicle; and
   a first supply device configured to supply, to the container, the inactive gas supplied to the supply receiving section,
the gas supply vehicle is further configured to travel along the travel path, and
the gas supply vehicle includes:
   a holding section configured to detachably hold a gas tank filled with the inactive gas;
   a supply section configured to be connected to and disconnected from the supply receiving section; and
   a second supply device configured to supply the inactive gas from the gas tank held by the holding section to the supply section.

The present configuration makes it possible to supply the inactive gas to the container that is being transported by the transport vehicle from the gas tank held by the gas supply vehicle by connecting the supply section to the supply receiving section. At this time, the gas supply vehicle can travel along the same travel path as the transport vehicle, and it is therefore possible to supply the inactive gas to the container, regardless of whether the transport vehicle is traveling or stopped. With the present configuration, the gas supply vehicle detachably holds the gas tank, and it is therefore possible to easily replace the gas tank. Accordingly, it is possible to provide a gas supply vehicle that can travel along the same travel path as the transport vehicle, while also ensuring the amount of the inactive gas that can be supplied by the gas supply vehicle to be large. As described above, the present configuration makes it possible to realize a gas supply system that can supply an inactive gas to a container that is being transported by a transport vehicle.

Further features and advantages of the present disclosure will become apparent from the following description of illustrative and non-limiting embodiments with reference to the drawings.

### BRIEF DESCRIPTION OF THE DRAWINGS

FIG. 1 is a plan view of a transport facility in which a gas supply system is used.

FIG. 2 is a side view showing a transport vehicle and a gas supply vehicle.

FIG. 3 is a control block diagram.

FIGS. 4A to 4D are explanatory diagrams showing connection and separation between a supply section and a supply receiving section.

FIG. 5 is an explanatory diagram showing replacement of a gas tank in a gas tank storage.

### DESCRIPTION OF THE INVENTION

A gas supply system is a system for supplying an inactive gas into a container, the gas supply system including a transport vehicle configured to travel along a predetermined travel path to transport the container. Hereinafter, an embodiment of the gas supply system will be described taking, as an example, a case where the gas supply system is used in a transport facility.

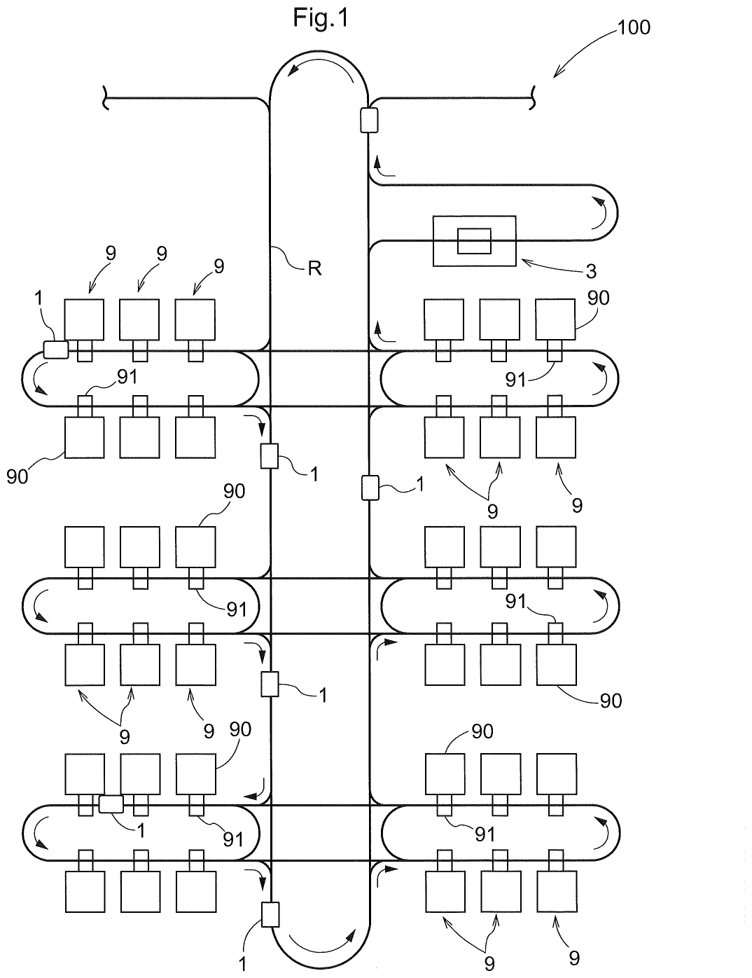

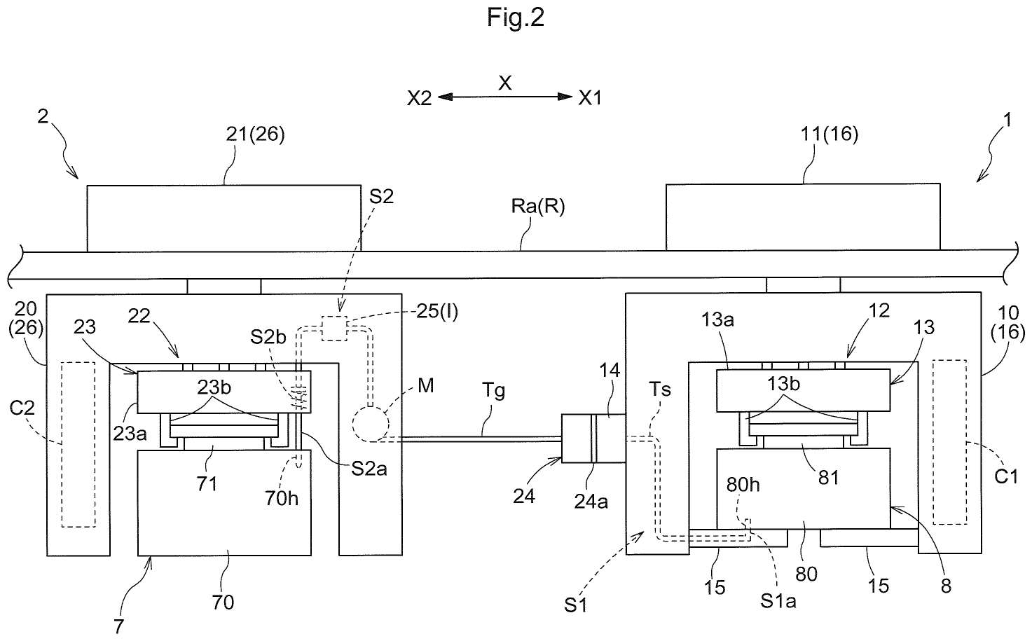

As shown in FIGS. 1 and 2, a transport facility 100 includes a predetermined travel path R, at least one transport vehicle 1 that travels along the travel path R to transport a container 8, and a plurality of transfer target locations 9 provided along the travel path R.

The travel path R is set at a position spaced upward from a floor surface. In the present example, the travel path R is formed using a rail Ra provided in the vicinity of a ceiling. The transport vehicle 1 is configured as an overhead transport vehicle, and travels along the rail Ra. The transfer target locations 9 are disposed below the travel path R. The transport vehicle 1 is configured to transfer a container 8 to and from each transfer target location 9 by elevating and lowering the container 8.

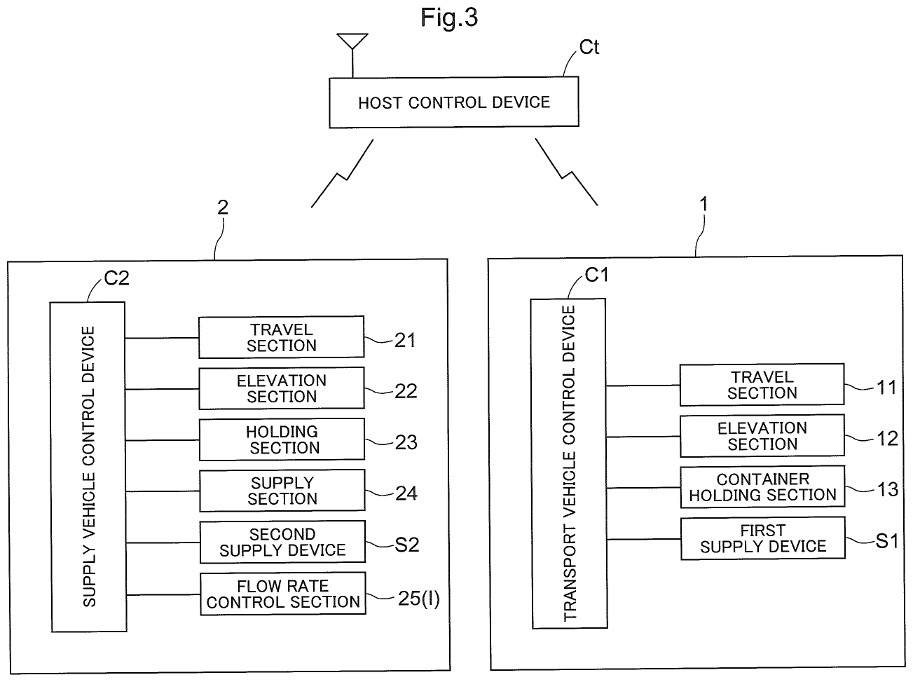

In the present embodiment, the transport facility 100 includes a plurality of transport vehicles 1. Each of the plurality of transport vehicles 1 is configured to receive a transport instruction from a host control device Ct (see FIG. 3) that manages overall control of the facility, and execute a task corresponding to the transport instruction. For example, the transport instruction contains information about a transport source and a transport destination of each container 8. The transport vehicle 1 that has received the transport instruction transports the container 8 from the transport source to the transport destination. The transport source and the transport destination include the transfer target locations 9.

The transport facility 100 handles various types of containers 8. In the present example, the transport facility 100 is used for a semiconductor manufacturing plant. Accordingly, each container 8 is configured to house a content object such as a semiconductor wafer and a glass substrate. Each transport vehicle 1 transports a container 8 housing these content objects along the travel path R over various steps.

In the present embodiment, each of the transfer target locations 9 includes a processing apparatus 90 that performs processing on a container 8, and a placement table 91 disposed adjacent to the processing apparatus 90. The expression “processing on a container 8” as used herein means processing on a content object (e.g., a semiconductor wafer or a glass substrate) housed in a container 8. Each of the transport vehicles 1 receives, from the placement table 91, a container 8 that has already been subjected to processing performed by the processing apparatus 90, or delivers, to the placement table 91, a container 8 that has not yet been subjected to processing performed by the processing apparatus 90. Note that the processing apparatus 90 performs various types of processing, including, for example, thin-film formation, photolithography, and etching.

As shown in FIG. 2, a transport vehicle 1 includes a vehicle body 16. The vehicle body 16 includes a support section 10 and a travel section 11. The transport vehicle 1 further includes an elevation section 12 and a container holding section 13. The elevation section 12 and the container holding section 13 are supported by the vehicle body 16 (here, the support section 10).

The support section 10 is configured to support a container 8. In the present embodiment, the support section 10 supports a container 8 by holding the container 8 using the container holding section 13. In the present embodiment, the support section 10 is configured to house a container 8. That is, the support section 10 has the function of a housing section for housing a container 8. In the case of transporting a container 8, the transport vehicle 1 travels along the travel path R with the container 8 housed in the support section 10. In the present embodiment, the support section 10 is disposed below the rail Ra.

The travel section 11 is configured to travel along the travel path R. The travel section 11 travels along the rail Ra. In the present embodiment, the travel section 11 is disposed above the rail Ra, and is coupled to the support section 10 disposed below the rail Ra. Although a detailed illustration has been omitted, the travel section 11 includes a plurality of wheels, and a drive source (e.g., an electric motor or the like) that drives at least some of the plurality of wheels.

The elevation section 12 is configured to elevate and lower the container holding section 13 between the vehicle body 16 (here, the support section 10; the same applies hereinafter), and a transfer target location 9 (see FIG. 1) disposed below the vehicle body 16. This enables the transport vehicle 1 to transfer a container 8 to and from the placement table 91 of the transfer target location 9. Although a detailed description has been omitted, the elevation section 12 includes an elevation belt coupled to the container holding section 13, and an elevation driving section configured to wind up and unwind the elevation belt.

The container holding section 13 is configured to hold a container 8. The container holding section 13 is configured to be elevated and lowered by the elevation section 12 between the vehicle body 16 and the transfer target location 9.

In the present embodiment, a container 8 includes a container body 80, and a held section 81 protruding upward from an upper surface of the container body 80. The container holding section 13 is configured to hold the held section 81 of the container 8. In the present example, the held section 81 of the container 8 is flange shaped. The container holding section 13 holds the container 8 in such a manner as to sandwich the flange-shaped held section 81 from both sides in the horizontal direction.

In the present embodiment, the container holding section 13 includes a holding body section 13a, and a pair of holding claws 13b protruding downward from the holding body section 13a. In the present example, the two holding claws 13b move toward or away from each other. The two holding claws 13b hold the container 8 by moving toward each other, and release the container 8 by moving away from each other. Note that the holding body section 13a is coupled to the elevation belt of the elevation section 12. The holding body section 13a is elevated as a result of the elevation belt being wound up. The holding body section 13a is lowered as a result of the elevation belt being unwound.

In the present embodiment, the transport vehicle 1 includes a fall restriction member 15 that restricts falling of the container 8 from the vehicle body 16. The fall restriction member 15 restricts falling of the container 8 housed in the support section 10 while being held by the container holding section 13.

The fall restriction member 15 is coupled to the support section 10, and is configured to extend and retract relative to the support section 10. In a protruding state in which the fall restriction member 15 protrudes from the support section 10, the fall restriction member 15 is disposed at a position facing, from below, the container 8 housed in the support section 10. Accordingly, even if the container 8 is dislodged from the container holding section 13 in the support section 10, it is possible to restrict falling of container 8 by the fall restriction member 15 in the protruding state. In a retracted state, the fall restriction member 15 is displaced from a route along which the container holding section 13 and the container 8 are elevated and lowered by the elevation section 12. This makes it possible to prevent the fall restriction member 15 from impeding elevation and lowering of the container holding section 13 and the container 8 performed by the elevation section 12.

Here, in such a semiconductor manufacturing plant, it is common that an inactive gas such as a nitrogen gas is supplied into a container, for example, in order to suppress oxidation of a content object (e.g., a semiconductor wafer or a glass substrate) housed in the container, or prevent dust from adhering to the content object. Conventionally, it is often the case that the inactive gas is supplied into the container while the container is stored in a specialized purge stocker. The gas supply system according to the present disclosure enables the inactive gas to be supplied into the container without using such a purge stocker. This will be described in detail below.

In the following, a direction extending along the travel path R is referred to as a “traveling direction X”. One side in the traveling direction X is referred to as a “first side X1 in the traveling direction”, and the other side in the traveling direction X is referred to as a “second side X2 in the traveling direction”. In the present embodiment, the first side X1 in the traveling direction is the front side in the traveling direction X. The second side X2 in the traveling direction is the rear side in the traveling direction X.

As shown in FIG. 2, the gas supply system includes a gas supply vehicle 2 that supplies an inactive gas to each transport vehicle 1. The gas supply vehicle 2 is configured to travel along the travel path R. Using the gas supply vehicle 2, the gas supply system supplies an inactive gas to the container 8 held by a transport vehicle 1 present on the travel path R. In the present example, the gas supply vehicle 2 is configured as a so-called overhead traveling vehicle that travels along the rail Ra provided in the vicinity of a ceiling.

Each transport vehicle 1 includes a supply receiving section 14 that receives the inactive gas supplied from the gas supply vehicle 2, and a first supply device S1 that supplies, to the container 8, the inactive gas supplied to the supply receiving section 14.

In the present embodiment, the supply receiving section 14 protrudes toward the second side X2 in the traveling direction from the vehicle body 16 of the transport vehicle 1. Here, the supply receiving section 14 protrudes toward the second side X2 in the traveling direction from the support section 10. As described above, in the present example, the second side X2 in the traveling direction is the rear side in the traveling direction X. Accordingly, the supply receiving section 14 protrudes rearward from a rear portion of the vehicle body 16 of the transport vehicle 1. The supply receiving section 14 is configured to be connected to the supply section 24 of the gas supply vehicle 2. Note that the supply receiving section 14 may protrude toward the second side X2 in the traveling direction from a portion (e.g., the travel section 11) of the vehicle body 16 that is different from the support section 10.

In the present embodiment, the first supply device S1 includes a supply pipe Ts through which the inactive gas supplied from the gas supply vehicle 2 flows, and a first nozzle S1a configured to be connected to the container 8 held by the container holding section 13. Although a detailed illustration has been omitted, in the present example, the first supply device S1 includes a solenoid valve capable of opening and closing a flow path of the inactive gas in the supply pipe Ts. The opening and closing operations of the solenoid valve are controlled by a transport vehicle control device C1 installed in the transport vehicle 1.

The supply pipe Ts connects the supply receiving section 14 and the first nozzle S1a with each other. In other words, one end portion of the supply pipe Ts is coupled to the supply receiving section 14, and the other end portion of the supply pipe Ts is coupled to the first nozzle S1a. In the present embodiment, the supply pipe Ts passes through the inside of the vehicle body 16 (here, the support section 10). In the present example, the supply pipe Ts passes through the inside of the support section 10, and extends along the fall restriction member 15. Also, the first nozzle S1a provided at a distal end of the supply pipe Ts protrudes upward from the fall restriction member 15.

In the present embodiment, in the case of receiving the inactive gas supplied from the gas supply vehicle 2, the transport vehicle 1 brings the fall restriction member 15 into the protruding state, and places the container 8 on the fall restriction member 15. Then, the first nozzle S1a protruding upward from the fall restriction member 15 is inserted into an insertion port 80h provided at a bottom portion of the container body 80. This enables the transport vehicle 1 to receive the inactive gas supplied from the gas supply vehicle 2.

The gas supply vehicle 2 includes a holding section 23 that detachably holds the gas tank 7 filled with the inactive gas, a supply section 24 configured to be connected to and disconnected from the supply receiving section 14 of the transport vehicle 1, and a second supply device S2 that supplies the inactive gas from the gas tank 7 held by the holding section 23 to the supply section 24. In addition, the gas supply vehicle 2 includes a vehicle body 26. The vehicle body 26 includes a support section 20 and a travel section 21. The transport vehicle 1 further includes an elevation section 22. The elevation section 22 and the holding section 23 are supported by the vehicle body 26 (here, the support section 20; the same applies hereinafter).

The support section 20 is configured to support the gas tank 7. In the present embodiment, the support section 20 supports the gas tank 7 by holding the gas tank 7 using the holding section 23. In the present embodiment, the support section 20 is configured to house the gas tank 7. That is, the support section 20 has the function of a housing section for housing the gas tank 7. In the case of transporting the gas tank 7, the gas supply vehicle 2 travels along the travel path R with the gas tank 7 housed in the support section 20. In the present embodiment, the support section 20 is disposed below the rail Ra.

The travel section 21 is configured to travel along the travel path R. The travel section 21 travels along the rail Ra. In the present embodiment, the travel section 21 is disposed above the rail Ra, and is coupled to the support section 20 disposed below the rail Ra. Although a detailed illustration has been omitted, the travel section 21 includes a plurality of wheels, and a drive source (e.g., an electric motor or the like) that drives at least some of the plurality of wheels.

The elevation section 22 is configured to elevate and lower the holding section 23. Although a detailed description has been omitted, the elevation section 22 includes an elevation belt coupled to the holding section 23, and an elevation driving section configured to wind up and unwind the elevation belt.

The holding section 23 is configured to hold the gas tank 7. The holding section 23 is configured to be elevated and lowered by the elevation section 22.

In the present embodiment, the gas tank 7 includes a tank body 70 in which an inactive gas (e.g., an inactive gas in a compressed state) is stored, and a held section 71 protruding upward from an upper surface of the tank body 70. The holding section 23 is configured to hold the held section 71 of the gas tank 7. In the present example, the held section 71 of the gas tank 7 is flange shaped. The holding section 23 holds the gas tank 7 in such a manner as to sandwich the flange-shaped held section 71 from both sides in the horizontal direction.

In the present embodiment, the holding section 23 includes a holding body section 23a, and a pair of holding claws 23b protruding downward from the holding body section 23a. In the present example, the holding claws 23b move toward or away from each other. The two holding claws 23b hold the gas tank 7 by moving toward each other, and release the gas tank 7 by moving away from each other. Note that the holding body section 23a is coupled to the elevation belt of the elevation section 22. The holding body section 23a is elevated as a result of the elevation belt being wound up. The holding body section 23a is lowered as a result of the elevation belt being unwound.

In the present embodiment, the second supply device S2 includes a gas pipe Tg through which the inactive gas from the gas tank 7 flows, and a second nozzle S2a configured to be connected to the gas tank 7 held by the holding section 23. Although a detailed illustration has been omitted, in the present example, the second supply device S2 includes a solenoid valve capable of blocking a flow path of the inactive gas in the gas pipe Tg. The opening and closing operations of the solenoid valve are controlled by a supply vehicle control device C2 installed in the gas supply vehicle 2.

The gas pipe Tg connects the supply section 24 and the second nozzle S2a with each other. In other words, one end portion of the gas pipe Tg is coupled to the supply section 24, and the other end portion of the gas pipe Tg is coupled to the second nozzle S2a.

In the present embodiment, the gas pipe Tg passes through the inside of the vehicle body 26 (here, the support section 20). A flow rate control section 25 that controls the flow rate of the inactive gas flowing through the gas pipe Tg is provided inside the vehicle body 26. The flow rate control section 25 is formed using a so-called mass flow controller.

In the present embodiment, the gas pipe Tg passes through the inside of the holding body section 23a, in addition to passing through the inside of the support section 20. The gas pipe Tg is coupled to the second nozzle S2a inside the holding body section 23a.

In the present embodiment, the second supply device S2 is connected to the gas tank 7 held by the holding section 23, in response to a change from a non-holding state, in which the holding section 23 is not holding the gas tank 7, to a holding state, in which the holding section 23 is holding the gas tank 7.

In the present embodiment, the second nozzle S2a protrudes downward from the holding body section 23a. The second nozzle S2a is inserted into an insertion port 70h provided at an upper portion of the tank body 70, in response to a change from the non-holding state, in which the holding section 23 is not holding the gas tank 7, to the holding state, in which the holding section 23 is holding the gas tank 7. Consequently, the second supply device S2 is connected to the gas tank 7 held by the holding section 23.

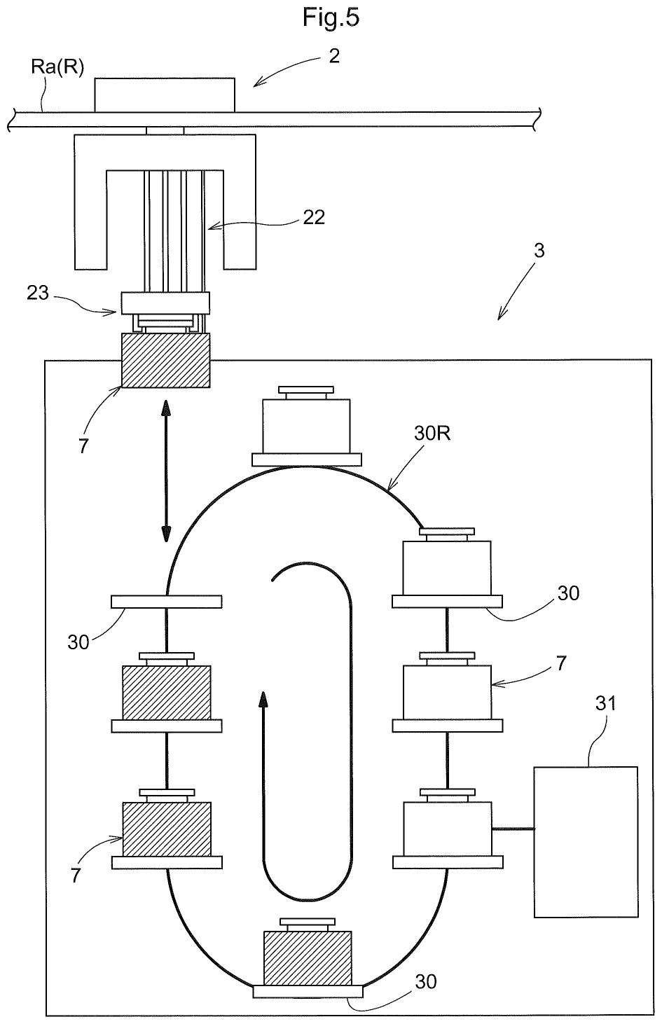

In the present embodiment, the gas supply vehicle 2 is configured to receive the gas tank 7 disposed below the vehicle body 26 (see also FIG. 5). In the case of receiving the gas tank 7, the gas supply vehicle 2 lowers the holding section 23 from the vehicle body 26 using the elevation section 22. The holding section 23 approaches a gas tank 7 to be received by being lowered. When the holding section 23 has been lowered to a position at which the holding section 23 can hold the gas tank 7, the second nozzle S2a protruding downward from the holding body section 23a is inserted into the insertion port 70h of the tank body 70. Then, the gas supply vehicle 2 holds the held section 71 of the gas tank 7 using the pair of holding claws 23b, and elevates the holding section 23 to the vehicle body 26 using the elevation section 22. Consequently, the gas supply vehicle 2 is brought into a state as shown in FIG. 2.

In the present embodiment, the second supply device S2 includes a biasing member S2b that biases the second nozzle S2a downward. The biasing member S2b is formed using an elastic body such as a spring. Since the biasing member S2b biases the second nozzle S2a downward, the second nozzle S2a can be appropriately inserted into the insertion port 70h of the tank body 70. In the present example, the biasing member S2b is provided inside the holding body section 23a.

In the present embodiment, the supply section 24 protrudes toward the first side X1 in the traveling direction from the vehicle body 26 of the gas supply vehicle 2. Here, the supply section 24 protrudes toward the first side X1 in the traveling direction from the support section 20. As described above, in the present example, the first side X1 in the traveling direction is the front side in the traveling direction X. Accordingly, the supply section 24 protrudes forward from a front portion of the vehicle body 26 of the gas supply vehicle 2. The supply section 24 is configured to be connected to the supply receiving section 14 of the transport vehicle 1. Note that the supply section 24 may protrude toward the first side X1 in the traveling direction from a portion (e.g., the travel section 21) of the vehicle body 26 that is different from the support section 20.

In the present embodiment, at least either the supply section 24 or the supply receiving section 14 is provided with an electromagnet 24a. Connection and disconnection of the supply section 24 and the supply receiving section 14 are controlled based on whether or not the electromagnet 24a is energized. In the present example, only the supply section 24 is provided with the electromagnet 24a. The supply receiving section 14 is configured to enable the electromagnet 24a to be attracted thereto. The supply receiving section 14 is formed using a permanent magnet or an iron material, for example. Conversely, the supply receiving section 14 may be provided with the electromagnet 24a.

In the present embodiment, the gas pipe Tg is flexible. That is, in the present embodiment, the second supply device S2 includes a flexible gas pipe Tg. The gas pipe Tg is wound around the rotational body M, and is unwound and wound up according to the inter-vehicle distance between the gas supply vehicle 2 and the transport vehicle 1. In the present example, the rotational body M is formed using a drive source such as an electric motor, and unwinds or winds up the gas pipe Tg using a driving force generated by the drive source. The rotational body M is provided inside the vehicle body 26. Note that the rotational body M may be provided with a mechanism for winding up the gas pipe Tg using a biasing force of a spring or the like, and the gas pipe Tg is unwound from the rotational body M against the biasing force in response to the inter-vehicle distance between the gas supply vehicle 2 and the transport vehicle 1 being increased, and the gas pipe Tg is wound up on the rotational body M by the biasing force in response to the inter-vehicle distance between the gas supply vehicle 2 and the transport vehicle 1 being decreased.

In the present embodiment, the gas pipe Tg extends from the vehicle body 26 of the gas supply vehicle 2 toward the first side X1 in the traveling direction, and the supply section 24 is attached to an end portion of the gas pipe Tg. Specifically, the gas pipe Tg is configured to extend from the vehicle body 26 of the gas supply vehicle 2 toward the first side X1 in the traveling direction. The gas supply vehicle 2 causes the gas pipe Tg to extend from the vehicle body 26 toward the first side X1 in the traveling direction by unwinding the flexible gas pipe Tg using the rotational body M. This configuration enables the transport vehicle 1 and the gas supply vehicle 2 to travel while maintaining a predetermined inter-vehicle distance therebetween in a state in which the supply receiving section 14 and the supply section 24 are connected to each other.

The gas supply vehicle 2 includes a remaining amount measuring instrument I that measures the remaining amount of the inactive gas in the gas tank 7. In the present embodiment, the remaining amount measuring instrument I measures the remaining amount of the inactive gas in the gas tank 7 based on the pressure of the inactive gas supplied by the gas tank 7. In the present example, the flow rate control section 25 measures the pressure of the inactive gas. That is, the flow rate control section 25 also functions as the remaining amount measuring instrument I. Next, a control configuration of the gas supply system will be described.

As shown in FIG. 3, the gas supply system includes a transport vehicle control device C1 that controls the transport vehicle 1, and a supply vehicle control device C2 that controls the gas supply vehicle 2. In the present embodiment, the gas supply system further includes a host control device Ct. The host control device Ct performs centralized control of the transport facility 100. The host control device Ct, the transport vehicle control device C1, and the supply vehicle control device C2 each include, for example, a processor such as a microcomputer, and a peripheral circuit such as a memory. Various functions are implemented by these pieces of hardware working cooperatively with a program executed on a processor such as a computer.

The transport vehicle control device C1 is installed in the transport vehicle 1. The transport vehicle control device C1 is configured to control the travel section 11, the elevation section 12, the container holding section 13, and the first supply device S1. The transport vehicle control device C1 controls, for example, driving units of various sections. In the case of controlling the first supply device S1, the transport vehicle control device C1 controls, for example, opening and closing of the solenoid valve provided in the supply pipe Ts.

The supply vehicle control device C2 is installed in the gas supply vehicle 2. The supply vehicle control device C2 is configured to control the travel section 21, the elevation section 22, the holding section 23, the supply section 24, the second supply device S2, and the flow rate control section 25 (remaining amount measuring instrument I). The supply vehicle control device C2 controls driving units of various sections, for example. In the case of controlling the second supply device S2, the supply vehicle control device C2 controls, for example, opening and closing of the solenoid valve provided in the gas pipe Tg, and operations of the rotational body M. In the case of controlling the supply section 24, the supply vehicle control device C2 controls the energization state of the electromagnet 24a provided in the supply section 24. Thus, connection and disconnection of the supply section 24 to and from the supply receiving section 14 is controlled.

The host control device Ct is configured to give the above-described transport instruction to each transport vehicle 1. The transport vehicle 1 that has received the transport instruction transports the container 8 from the designated transport source to a transport destination.

In the present embodiment, the host control device Ct is configured to designate, for the gas supply vehicle 2, a target transport vehicle 1 to which the inactive gas is to be supplied, and give a gas supply instruction to the gas supply vehicle 2. The gas supply vehicle 2 that has received the gas supply instruction travels to a position adjacent to the target transport vehicle 1, and supplies the inactive gas to the container 8 held by the target transport vehicle 1.

In the present embodiment, the host control device Ct measures, for each of the transport vehicles 1 in the transport facility 100, an elapsed time since the start of transport of a container 8 filled with the inactive gas. The container 8 is not completely sealed, and therefore the inactive gas leaks from the inside of the container 8 with passage of time, resulting in a reduction in the remaining amount of the inactive gas inside the container 8. In response to the elapsed time since the transport vehicle 1 started transporting the container 8 filled with the inactive gas having reached a set time that is set in advance, the host control device Ct designates the transport vehicle 1 holding the container 8 as a target transport vehicle 1, and gives a gas supply instruction to the gas supply vehicle 2 to supply the inactive gas to the target transport vehicle 1. This allows the gas supply vehicle 2 to head for the transport vehicle 1 holding a container 8 with a low remaining amount of the inactive gas, and supply the inactive gas to the container 8. The above-described set time may be set as appropriate according to the performance of the container 8, the type of the inactive gas, and other factors or the like.

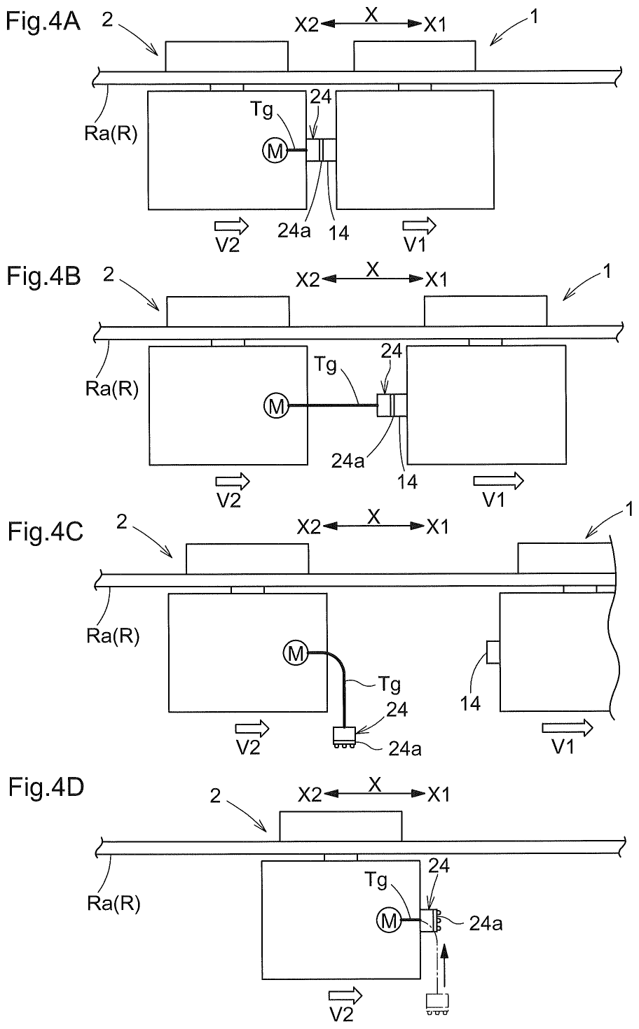

FIGS. 4A to 4D show a state from the start of supply of the inactive gas to the transport vehicle 1 performed by the gas supply vehicle 2 to the end of the supply of the inactive gas.

As shown in FIG. 4A, the gas supply vehicle 2 heads for a target transport vehicle 1 designated by a gas supply instruction. The gas supply vehicle 2 travels to a position adjacent to the target transport vehicle 1 on the second side X2 in the traveling direction, and connects the supply receiving section 14 of the target transport vehicle 1 and the supply section 24 of the gas supply vehicle 2 to each other. In the present embodiment, the connection of the supply section 24 to the supply receiving section 14 is achieved by bringing the electromagnet 24a into an energized state. When the electromagnet 24a is in the energized state, the connection between the supply receiving section 14 and the supply section 24 is maintained.

In the present embodiment, in the case of receiving the inactive gas supplied from the gas supply vehicle 2, the target transport vehicle 1 makes a traveling speed V1 to zero. That is, while the target transport vehicle 1 is stopped on the travel path R, the gas supply vehicle 2 approaches the target transport vehicle 1 from the second side X2 in the traveling direction, and connects the supply section 24 to the supply receiving section 14. After the supply receiving section 14 and the supply section 24 have been connected to each other, the gas supply vehicle 2 starts supply of the inactive gas to the target transport vehicle 1 (specifically, the container 8 held by the target transport vehicle 1).

As shown in FIG. 4B, while the gas supply vehicle 2 is supplying the inactive gas to the target transport vehicle 1, the traveling speed V1 of the target transport vehicle 1 and the traveling speed V2 of the gas supply vehicle 2 may have a value larger than zero. That is, the target transport vehicle 1 and the gas supply vehicle 2 both may travel along the travel path R.

In the present embodiment, the gas supply vehicle 2 is configured to follow the target transport vehicle 1 in such a manner as to maintain a constant distance from the target transport vehicle 1. In this case, the gas pipe Tg to which the supply section 24 is coupled extends from the gas supply vehicle 2 toward the first side X1 in the traveling direction. The amount of extension of the gas pipe Tg is adjusted by the rotational body M according to the inter-vehicle distance between the gas supply vehicle 2 and the target transport vehicle 1.

The above-described following travel can be realized by the gas supply vehicle 2 and the target transport vehicle 1 communicating with each other to travel at the same traveling speeds (V1, V2). This communication may be performed via the host control device Ct. The above-described following travel may also be performed as follows. For example, the gas supply vehicle 2 includes a detection section that detects the inter-vehicle distance from the target transport vehicle 1, and the traveling speed V2 is controlled in such a manner that a result obtained by the detection section is constant, or in other words, the inter-vehicle distance is constant.

As shown in FIG. 4C, the gas supply vehicle 2 separates the supply section 24 and the supply receiving section 14 from each other in response to completion of supply of the inactive gas to the target transport vehicle 1. In the present embodiment, the gas supply vehicle 2 releases the attraction of the supply section 24 onto the supply receiving section 14 by bringing the electromagnet 24a into a de-energized state. The target transport vehicle 1 maintains or increases the traveling speed V1 to continue transport of the container 8. The gas supply vehicle 2 reduces the traveling speed V2 thereof to be lower than at least the traveling speed V1 of the target transport vehicle 1. Thus, the inter-vehicle distance between the target transport vehicle 1 and the gas supply vehicle 2 is gradually increased. At this time, the gas pipe Tg that has extended from the gas supply vehicle 2 hangs down from the gas supply vehicle 2 as shown in FIG. 4C.

As shown in FIG. 4D, after separating the supply section 24 from the supply receiving section 14, the gas supply vehicle 2 winds up the gas pipe Tg using the rotational body M. Thus, the gas pipe Tg that has hung down from the gas supply vehicle 2 is housed inside the gas supply vehicle 2. The supply section 24 attached to the distal end of the gas pipe Tg is returned to the original position, i.e., the front portion of the vehicle body 26.

Here, as described above, the holding section 23 of the gas supply vehicle 2 is configured to detachably hold the gas tank 7. In the present embodiment, in response to the remaining amount of the gas tank 7 held by the gas supply vehicle 2 becoming low or empty as a result of supplying the inactive gas to the transport vehicle 1, the gas supply vehicle 2 replaces the gas tank 7 with a new gas tank 7 filled with the inactive gas.

As shown in FIG. 5, in the present embodiment, the gas supply system includes a gas tank storage 3 that stores the gas tank 7. The gas tank storage 3 is provided at a specific location on the travel path R (see also FIG. 1).

Based on a result of measurement performed by the remaining amount measuring instrument I, the gas supply vehicle 2 moves to the gas tank storage 3, and replaces a used gas tank 7 with a gas tank 7 filled with the inactive gas in the gas tank storage 3. In response to a result of measurement performed by the remaining amount measuring instrument I being a defined value defined in advance, or being zero, the gas supply vehicle 2 heads for the gas tank storage 3, and replaces the gas tank 7 in the gas tank storage 3.

In the present embodiment, the gas supply vehicle 2 includes a transfer device that transfers the gas tank 7 between the vehicle body 26 and the gas tank storage 3. In the present example, the transfer device includes the elevation section 22 and the holding section 23, and the gas supply vehicle 2 transfers the gas tank 7 in a vertical direction. That is, the gas supply vehicle 2 is configured to transfer the gas tank 7 to and from the gas tank storage 3 by holding the gas tank 7 using the holding section 23 and elevating and lowering the holding section 23 using the elevation section 22.

In the present embodiment, the gas tank storage 3 includes a plurality of support platforms 30. Each of the plurality of support platforms 30 is configured to support a gas tank 7. A used gas tank 7 that has been received from the gas supply vehicle 2, or a gas tank 7 filled with the inactive gas is supported on each support platform 30.

For example, the plurality of support platforms 30 are configured to circulate the inside of the gas tank storage 3 along a circulation path 30R. In the case of replacing a used gas tank 7, the gas supply vehicle 2 delivers the used gas tank 7 to a support platform 30 on which nothing is supported. The support platform 30 that has received the used gas tank 7 and a support platform 30 that supports a gas tank 7 filled with the inactive gas are moved along the circulation path 30R, and the positions of the support platforms 30 are shifted. Then, the gas supply vehicle 2 receives the gas tank 7 filled with the inactive gas from the support platform 30 at the shifted position. In the illustrated example, the circulation path 30R along which the plurality of support platforms 30 move is formed around a horizontal axis. However, the circulation path 30R is not limited to such a configuration, and may be formed around a vertical axis. The plurality of support platforms 30 may also be fixed at predetermined positions in the gas tank storage 3. In this case, a gas tank 7 may be placed on each support platform 30 using transporting means such as a conveyor or a robot arm.

In the present embodiment, the gas tank storage 3 includes a gas filling device 31 that fills the gas tank 7 with the inactive gas. The gas filling device 31 is configured to fill the used gas tank 7 received from the gas supply vehicle 2 with the inactive gas.

In the present embodiment, the gas filling device 31 is disposed adjacent to the circulation path 30R along which the plurality of support platforms 30 move. The gas filling device 31 fills a used gas tank 7 that has circulated along the circulation path 30R with the inactive gas. The gas tank 7 that has been filed with the inactive gas by the gas filling device 31 moves along the circulation path 30R again.

In this manner, in the present embodiment, the gas supply vehicle 2 itself can deliver a used gas tank 7 to the gas tank storage 3, and receive a gas tank 7 filled with the inactive gas from the gas tank storage 3. Accordingly, a cycle of supplying the inactive gas to the container 8 held by each transport vehicle 1 can be easily realized automatically. Since the gas tank storage 3 includes the gas filling device 31 that fills a used gas tank 7 with the inactive gas, a gas tank 7 filled with the inactive gas can be easily secured in the gas tank storage 3.

With the gas supply system described above, it is possible to supply the inactive gas to a container 8 that is being transported by each transport vehicle 1.

### OTHER EMBODIMENTS

Next, other embodiments of the gas supply system will be described.

(1) The above embodiment has described an example in which the second supply device S2 is connected to the gas tank 7 held by the holding section 23, in response to a change from a non-holding state, in which the holding section 23 is not holding the gas tank 7, to a holding state, in which the holding section 23 is holding the gas tank 7. However, the present disclosure is not limited to such an example, and the second supply device S2 may be connected to the gas tank 7 held by the holding section 23 at a timing when the inactive gas is supplied to the container 8 held by the transport vehicle 1. That is, in this case, a hold of the gas tank 7 by the holding section 23 has been completed before the second supply device S2 is connected to the gas tank 7.

(2) The above embodiment has described an example in which at least one of the supply section 24 and the supply receiving section 14 is provided with the electromagnet 24a, and connection and disconnection between the supply section 24 and the supply receiving section 14 are controlled based on whether or not the electromagnet 24a is energized. However, the present disclosure is not limited to such an example. For example, the supply section 24 and the supply receiving section 14 may include mutually corresponding protrusions or recesses, and be configured to be engaged with and disengaged from each other.

(3) The above embodiment has described an example in which the gas pipe Tg extends from the vehicle body 26 of the gas supply vehicle 2 toward the first side X1 in the traveling direction, and the supply section 24 is attached to an end portion of the gas pipe Tg. However, the present disclosure is not limited to such an example. The gas pipe Tg may stay inside the vehicle body 26 of the gas supply vehicle 2, and the supply section 24 may be fixed to an end portion of the vehicle body 26 on the first side X1 in the traveling direction. In this case, it is difficult to secure an inter-vehicle distance between the gas supply vehicle 2 and the transport vehicle 1. Accordingly, the gas supply vehicle 2 and the transport vehicle 1 may be coupled to each other using a coupling mechanism, and may travel while the inter-vehicle distance is substantially zero. This allows the transport vehicle 1 and the gas supply vehicle 2 to appropriately travel along the travel path R while maintaining a connected state between the supply section 24 and the supply receiving section 14. In the aforementioned case, the supply section 24 and the supply receiving section 14 may be provided in a coupling mechanism configured to couple the gas supply vehicle 2 and the transport vehicle 1 to each other. In a configuration in which the transport vehicle 1 and the gas supply vehicle 2 are coupled to each other using a coupling mechanism, the gas supply vehicle 2 may be towed by the transport vehicle 1 without traveling autonomously.

(4) The above embodiment has described an example in which, while the target transport vehicle 1 is stopped on the travel path R, the gas supply vehicle 2 approaches the target transport vehicle 1 from the second side X2 in the traveling direction, and connects the supply section 24 to the supply receiving section 14. However, the present disclosure is not limited to such an example. The gas supply vehicle 2 may approach the traveling target transport vehicle 1 from the second side X2 in the traveling direction, and connect the supply section 24 to the supply receiving section 14. In this case, it is preferable that the target transport vehicle 1 is traveling slowly.

(5) The above embodiment has described an example in which the first side X1 in the traveling direction is the front side in the traveling direction X, and the second side X2 in the traveling direction is the rear side in the traveling direction X. However, the present disclosure is not limited to such an example, and the front/rear relationship may be reversed. That is, the first side X1 in the traveling direction may be the rear side in the traveling direction X, and the second side X2 in the traveling direction may be the front side in the traveling direction X. Accordingly, in the case where the gas supply vehicle 2 supplies the inactive gas to the transport vehicle 1, the gas supply vehicle 2 may be disposed forwardly adjacent to the transport vehicle 1.

(6) The above embodiment has described an example in which the transfer device included in the gas supply vehicle 2 includes the elevation section 22 and the holding section 23, and the gas supply vehicle 2 transfers the gas tank 7 in the vertical direction. However, the present disclosure is not limited to such an example. The transfer device may include a horizontal movement mechanism (e.g., a fork section or a conveyor section) configured to move the gas tank 7 in the horizontal direction, and the gas supply vehicle 2 may be configured to transfer the gas tank 7 in the horizontal direction.

(7) The above embodiment has described an example in which the gas supply vehicle 2 includes the transfer device that transfers the gas tank 7 between the vehicle body 26 and the gas tank storage 3, and the gas supply vehicle 2 replaces the gas tank 7 by itself. However, the present disclosure is not limited to such an example, and the gas supply vehicle 2 need not include the above-described transfer device. In this case, the gas tank 7 may be replaced manually.

(8) The above embodiment has described an example in which the remaining amount measuring instrument I measures the remaining amount of the inactive gas in the gas tank 7 based on the pressure of the inactive gas supplied by the gas tank 7. However, the present disclosure is not limited to such an example, and the remaining amount measuring instrument I may be configured to measure the remaining amount of the inactive gas in the gas tank 7 based on the weight of the gas tank 7.

(9) The above embodiment has described an example in which the transport vehicle 1 serves to transport the container 8, and the gas supply vehicle 2 serves to supply the inactive gas. However, the present disclosure is not limited to such an example, and the transport vehicle 1 may have the function of the gas supply vehicle 2. Alternatively, the gas supply vehicle 2 may have the function of the transport vehicle 1. In other words, it (carriage) may function as the transport vehicle 1 in the case of holding the container 8, and may function as the gas supply vehicle 2 in the case of holding the gas tank 7.

(10) The above embodiment has described an example in which the gas supply system includes the gas tank storage 3. However, the gas tank storage 3 is not an essential component, and the gas supply system need not include such a gas tank storage 3.

(11) The above embodiment has described an example in which the gas supply vehicle 2 is configured as a so-called overhead traveling vehicle that travels along the rail Ra provided in the vicinity of a ceiling. However, the present disclosure is not limited to such an example, and it is sufficient that the gas supply vehicle 2 is configured to travel along the travel path R along which the transport vehicle 1 travels. For example, in the case where the transport vehicle 1 is configured to travel along a travel path R that is set along a floor surface, the gas supply vehicle 2 is similarly configured to travel along the travel path R set on the floor surface. That is, the transport vehicle 1 may be configured as a floor transport vehicle, and the gas supply vehicle 2 may be configured as a floor traveling vehicle.

(12) Note that the configurations disclosed in the embodiments described above are applicable in combination with configurations disclosed in other embodiments as long as no inconsistency arises. With regard to the other configurations as well, the embodiments disclosed herein are illustrative in all respects. Therefore, various modifications and alterations may be made as appropriate without departing from the gist of the present disclosure.

### Outline of the Embodiment

The gas supply system described above will be described below.

A gas supply system configured to supply an inactive gas into a container, the gas supply system including:
a transport vehicle configured to travel along a predetermined travel path and transport the container; and
a gas supply vehicle configured to supply the inactive gas to the transport vehicle,
wherein the transport vehicle includes:
   a supply receiving section configured to receive the inactive gas supplied from the gas supply vehicle; and
   a first supply device configured to supply, to the container, the inactive gas supplied to the supply receiving section,
the gas supply vehicle is further configured to travel along the travel path, and
the gas supply vehicle includes:
   a holding section configured to detachably hold a gas tank filled with the inactive gas;
   a supply section configured to be connected to and disconnected from the supply receiving section; and
   a second supply device configured to supply the inactive gas from the gas tank held by the holding section to the supply section.

The present configuration makes it possible to supply the inactive gas to the container that is being transported by the transport vehicle from the gas tank held by the gas supply vehicle by connecting the supply section to the supply receiving section. At this time, the gas supply vehicle can travel along the same travel path as the transport vehicle, and it is therefore possible to supply the inactive gas to the container, regardless of whether the transport vehicle is traveling or stopped. With the present configuration, the gas supply vehicle detachably holds the gas tank, and it is therefore possible to easily replace the gas tank. Accordingly, it is possible to provide a gas supply vehicle that can travel along the same travel path as the transport vehicle, while also ensuring the amount of the inactive gas that can be supplied by the gas supply vehicle to be large. As described above, the present configuration makes it possible to realize a gas supply system that can supply an inactive gas to a container that is being transported by a transport vehicle.

It is preferable that the second supply device is connected to the gas tank held by the holding section, in response to a change from a non-holding state, in which the holding section is not holding the gas tank, to a holding state, in which the holding section is holding the gas tank.

With the present configuration, it is possible to connect the second supply device to the gas tank in response to the gas tank being held by the holding section. Accordingly, the gas tank can be connected reliably.

It is preferable that the supply section protrudes from a body of the gas supply vehicle toward a first side in a traveling direction extending along the travel path,
the supply receiving section protrudes from a body of the transport vehicle toward a second side in the traveling direction,
at least either the supply section or the supply receiving section is provided with an electromagnet, and
connection and disconnection of the supply section and the supply receiving section are controlled based on whether or not the electromagnet is energized.

The present configuration makes it possible to easily connect the supply section and the supply receiving section to each other while the transport vehicle and the gas supply vehicle are traveling in line in the traveling direction. With the present configuration, connection and disconnection of the supply section and the supply receiving section is controlled using the electromagnet, and therefore the connection and disconnection can be easily performed.

It is preferable that the gas supply vehicle is further configured to follow a target transport vehicle, which is the transport vehicle to which the inactive gas is to be supplied, in such a manner as to maintain a constant distance from the target transport vehicle,
the second supply device includes a flexible gas pipe, and
the gas pipe extends from the body of the gas supply vehicle toward the first side in the traveling direction, and the supply section is attached to an end portion of the gas pipe.

With the present configuration, even while the target transport vehicle is traveling, it is possible to place the gas supply vehicle at a position at a certain distance from the target transport vehicle, and continue supply of the inactive gas to the container held by the target transport vehicle. At this time, the gas pipe that connects the gas supply vehicle and the target transport vehicle with each other is flexible, and it is therefore possible to appropriately continue supply of the gas even if the distance between the gas supply vehicle and the target transport vehicle has fluctuated to some degree during traveling.

It is preferable that the gas pipe is wound around a rotational body, and is unwound and wound up according to an inter-vehicle distance between the gas supply vehicle and the transport vehicle.

With the present configuration, even if the inter-vehicle distance between the gas supply vehicle and the transport vehicle has fluctuated while the inactive gas is supplied, it is possible to continue supply of the inactive gas while accommodating the fluctuation in the inter-vehicle distance as a result of the gas pipe being unwound and wound up. While supply of the inactive gas is not performed, and the supply section of the gas supply vehicle and the supply receiving section of the transport vehicle are separated from each other, it is possible to prevent the gas pipe from hanging down from the gas supply vehicle by sufficiently winding the gas pipe.

It is preferable that the gas supply system further includes a gas tank storage configured to store the gas tank,
wherein the gas supply vehicle further includes a transfer device configured to transfer the gas tank between a body of the gas supply vehicle and the gas tank storage.

With the present configuration, the gas tank held by the gas supply vehicle can be replaced automatically without any manual work.

It is preferable that the gas supply vehicle further includes a remaining amount measuring instrument configured to measure a remaining amount of the inactive gas in the gas tank, and, based on a result of measurement performed by the remaining amount measuring instrument, the gas supply vehicle moves to the gas tank storage, and replaces, in the gas tank storage, a used gas tank with a gas tank filled with the inactive gas.

With the present configuration, the gas supply vehicle itself can deliver a used gas tank to the gas tank storage, and receive a gas tank filled with the inactive gas from the gas tank storage. Accordingly, a cycle of supplying the inactive gas to the container held by the vehicle can be easily realized automatically.

It is preferable that the gas tank storage includes a gas filling device configured to fill the gas tank with the inactive gas, and
the gas filling device fills a used gas tank received from the gas supply vehicle with the inactive gas.

With the present configuration, a gas tank filled with the inactive gas can be easily secured in the gas tank storage.

The technique according to the present disclosure is applicable to a gas supply system for supplying an inactive gas into a container, the gas supply system including a transport vehicle that travels along a predetermined travel path to transport the container.

What is claimed is:

1. A gas supply system configured to supply an inactive gas into a container, the gas supply system comprising:
a transport vehicle configured to travel along a predetermined travel path and transport the container; and
a gas supply vehicle configured to supply the inactive gas to the transport vehicle,
wherein the transport vehicle comprises:
a supply receiving section configured to receive the inactive gas supplied from the gas supply vehicle; and
a first supply device configured to supply, to the container, the inactive gas supplied to the supply receiving section,
the gas supply vehicle is further configured to travel along the travel path, and
wherein the gas supply vehicle comprises:
a holding section configured to detachably hold a gas tank filled with the inactive gas;
a supply section configured to be connected to and disconnected from the supply receiving section; and
a second supply device configured to supply the inactive gas from the gas tank held by the holding section to the supply section.

2. The gas supply system according to claim 1,
wherein the second supply device is connected to the gas tank held by the holding section, in response to a change from a non-holding state, in which the holding section is not holding the gas tank, to a holding state, in which the holding section is holding the gas tank.

3. The gas supply system according to claim 1, wherein:
the supply section protrudes from a body of the gas supply vehicle toward a first side in a traveling direction extending along the travel path,
the supply receiving section protrudes from a body of the transport vehicle toward a second side in the traveling direction,
at least either the supply section or the supply receiving section is provided with an electromagnet, and
connection and disconnection of the supply section and the supply receiving section are controlled based on whether or not the electromagnet is energized.

4. The gas supply system according to claim 3, wherein:
the gas supply vehicle is further configured to follow a target transport vehicle, which is the transport vehicle to which the inactive gas is to be supplied, in such a manner as to maintain a constant distance from the target transport vehicle,
the second supply device comprises a flexible gas pipe, and
the gas pipe extends from the body of the gas supply vehicle toward the first side in the traveling direction, and the supply section is attached to an end portion of the gas pipe.

5. The gas supply system according to claim 4,
wherein the gas pipe is wound around a rotational body, and is unwound and wound up according to an inter-vehicle distance between the gas supply vehicle and the transport vehicle.

6. The gas supply system according to claim 1,
further comprising a gas tank storage configured to store the gas tank, and
wherein the gas supply vehicle further comprises a transfer device configured to transfer the gas tank between a body of the gas supply vehicle and the gas tank storage.

7. The gas supply system according to claim 6,
wherein the gas supply vehicle further comprises a remaining amount measuring instrument configured to measure a remaining amount of the inactive gas in the gas tank, and
wherein, based on a result of measurement performed by the remaining amount measuring instrument, the gas supply vehicle moves to the gas tank storage, and replaces, in the gas tank storage, a used gas tank with a gas tank filled with the inactive gas.

8. The gas supply system according to claim 6,
wherein the gas tank storage comprises a gas filling device configured to fill the gas tank with the inactive gas, and
wherein the gas filling device fills a used gas tank received from the gas supply vehicle with the inactive gas.
